(19) United States
(12) Patent Application Publication
(10) Pub. No.: US 2016/0303838 A1
(43) Pub. Date: Oct. 20, 2016

(54) TRANSPARENT CONDUCTIVE MULTILAYER ASSEMBLY

(71) Applicant: 3M INNOVATIVE PROPERTIES COMPANY, Saint Paul, MN (US)

(72) Inventors: Wan-Chun Chen, Zhubei City (TW); Chun-Ming Chiu, Zhubei City (TW); Hui Luo, Woodbury, MN (US); Tze Yuan Wang, New Taipei City (TW); Ta-Hua Yu, Woodbury, MN (US)

(21) Appl. No.: 15/102,866

(22) PCT Filed: Dec. 8, 2014
(86) PCT No.: PCT/US2014/068993

§ 371 Date: Jun. 8, 2016

Related U.S. Application Data
(60) Provisional application No. 61/913,513, filed on Dec. 9, 2013.

(51) Int. Cl. B32B 27/36; C23C 14/18; B32B 27/06; C23C 14/08; G06F 3/041; B32B 7/12

(52) U.S. Cl. CPC B32B 27/36; G06F 3/041; B32B 7/12; B32B 27/06; C23C 14/086; C23C 14/185; G06F 2203/04102; G06F 2203/04107; B32B 2307/412; B32B 2307/546; B32B 2457/208; B32B 2255/10; B32B 2255/20; B32B 2255/205; B32B 2255/26; B32B 2255/28; C23C 14/34

(57) ABSTRACT

A transparent multilayer assembly, including a transparent organic polymeric flexible substrate, a transparent conductive layer on the first major surface of the substrate and an antireflective layer on the second major surface of the substrate.

### BACKGROUND

Consumer electronic devices frequently employ touch screen displays where good electrical and optical properties are required simultaneously.

### SUMMARY

In broad summary, herein is disclosed a transparent multilayer assembly comprising a transparent organic polymeric flexible substrate, a transparent conductive layer on the first major surface of the substrate and an antireflective layer on the second major surface of the substrate. These and other aspects will be apparent from the detailed description below. In no event, however, should this broad summary be construed to limit the claimable subject matter, whether such subject matter is presented in claims in the application as initially filed or in claims that are amended or otherwise presented in prosecution.

### BRIEF DESCRIPTION OF THE DRAWINGS

FIG. 1 is a cross section side schematic view of an exemplary transparent multilayer assembly as disclosed herein.

FIG. 2 is a cross section side schematic view of an exemplary transparent multilayer assembly in which a transparent conductive layer of the assembly is comprised of a transparent conductive multilayer stack.

FIG. 3 is a cross section side schematic view of the transparent multilayer assembly of FIG. 1, combined with an optically clear adhesive to form an electromagnetic interference shielding assembly.

FIG. 4 is a cross section side schematic view of an exemplary touch screen display comprising a touch screen module comprising the electromagnetic interference shielding assembly of FIG. 3.

Like reference numbers in the various figures indicate like elements. Some elements may be present in identical or equivalent multiples; in such cases only one or more representative elements may be designated by a reference number but it will be understood that such reference numbers apply to all such identical elements. Unless otherwise indicated, all figures and drawings in this document are not to scale and are chosen for the purpose of illustrating different embodiments of the invention. In particular the dimensions of the various components are depicted in illustrative terms only, and no relationship between the dimensions of the various components should be inferred from the drawings, unless so indicated. Although terms such as “top”, bottom”, “upper”, lower”, “under”, “over”, “front”, “back”, “outward”, “inward”, “up” and “down”, and “first” and “second” may be used in this disclosure, it should be understood that those terms are used in their relative sense only unless otherwise noted. As used herein as a modifier to a property or attribute, the term “generally”, unless otherwise specifically defined, means that the property or attribute would be readily recognizable by a person of ordinary skill but without requiring absolute precision or a perfect match (e.g., within +/−20% for quantifiable properties). The term “substantially”, unless otherwise specifically defined, means to a high degree of approximation (e.g., within +/−10% for quantifiable properties) but again without requiring absolute precision or a perfect match. Terms such as same, equal, uniform, constant, strictly, and the like, are understood to be within the usual tolerances or measuring error applicable to the particular circumstance rather than requiring absolute precision or a perfect match.

### DETAILED DESCRIPTION

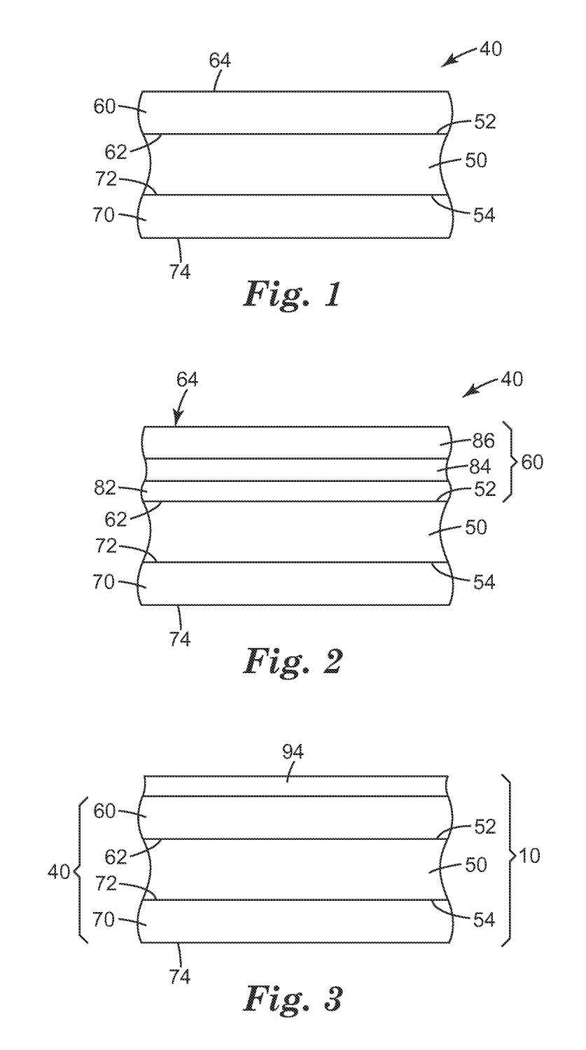

Shown in FIG. 1 in side schematic cross sectional view is an exemplary transparent multilayer assembly 40. Assembly 40 comprises a transparent organic polymeric flexible substrate 50 with first and second opposed major surfaces 52 and 54. A transparent conductive layer 60 with opposed major surfaces 62 and 64 is disposed on the first side of substrate 50 with first major surface 62 of conductive layer 60 in direct contact with first major surface 52 of substrate 50. A transparent antireflective layer 70 with opposed major surfaces 72 and 74 is disposed on the second, opposite side of substrate 50 with first major surface 72 of antireflective layer 70 in direct contact with second major surface 54 of substrate 50.

Transparent organic polymeric flexible substrate 50 may be comprised of any suitable material that exhibits the requisite properties of transparency, resistance to aging effects, temperature resistance, and so on. Suitable materials may include e.g. polycarbonate, cyclo-olefin copolymer, poly(methyl methacrylate), and so on. Any copolymer, blends, and so on, of any such material may be used. Any suitable additive may be present for any purpose as long as it does not interfere with the e.g. optical properties of the material. In many embodiments, substrate 50 may be comprised of polyester (e.g., polyethylene terephthalate, polyethylene naphthalate, and copolymers and blends thereof). In some embodiments, transparent organic polymeric flexible substrate 50 may consist of a single integral organic polymeric film of uniform composition throughout the thickness of the film. In many embodiments, such a film may be a non-conducting (i.e., electrically insulative) film. For example, an optical grade polyester film may be used, without any layer (e.g., coating) of organic or inorganic material on a major surface thereof. In some such embodiments, both major surfaces of such a film will thus be of substantially the same composition as the interior portions of the film. In particular embodiments, substrate 50 may be comprised of optical grade polyester film that does not comprise any kind of surface layer (e.g., primer or tie layer), coating, any kind of treatment that might alter the surface chemistry (e.g., such as plasma, corona, and so on), and so on. In some embodiments such a polyester film may be free of e.g. surface roughening (as achieved by the presence of silica particles or by some other surface-roughening method) of a size scale that is sometimes provided on a surface of some polyester films to provide anti-stick properties and the like. In various embodiments, the optical transmittance of such a film substrate (in the absence of any conductive layer, antireflective coating, etc.) may be at least about 88, 89, 90, or 91%.

In other embodiments, transparent organic polymeric flexible substrate 50 may comprise an organic polymeric film with at least one layer of material provided on a major surface thereof, so that substrate 50 is a multilayer substrate. (Such arrangements are allowed as long as other requirements disclosed herein are met). In some embodiments, such a layer of material may be an organic polymeric material that is e.g. coated (e.g. by liquid coating), vapor deposited (e.g., by vapor deposition/condensation processes, of the general type disclosed e.g. in U.S. Pat. No. 5,440,446), or the like. In some embodiments, substrate 50 may comprise a multilayer film as obtained e.g. by multilayer extrusion. In some embodiments, substrate 50 may comprise a priming treatment on one or both major surfaces.

Transparent conductive layer 60 can be comprised of any suitable transparent conductive material. By “conductive” is meant that layer 60 exhibits an average sheet resistance of less than about 500 Ohm/sq. In various embodiments, conductive layer 60 may comprise e.g. one or more metals, metal oxides, conductive polymers, and so on. In some embodiments, conductive layer 60 may take the form of a continuous layer (noting that this does not preclude the presence of a very low number of occasional defects as may be statistically unavoidable in coating processes). In other embodiments, conductive layer 60 may comprise, or take the form of, a discontinuous layer (e.g., a network such as a metal mesh, a metal nanowire structure, and the like). In particular embodiments, conductive layer 60 may comprise metal (e.g., silver) nanowires of the general type disclosed e.g. in U.S. Pat. No. 8,049,333. In other embodiments, conductive layer 60 may comprise e.g. a conductive polymer, graphene, carbon nanotubes, and so on.

In some embodiments, transparent conductive layer 60 may take the form of a multilayer stack (e.g., a three layer stack) as shown in exemplary embodiment in FIG. 2. In some embodiments, such a multilayer stack may comprise a low index of refraction conductive core layer 84 with first and second opposed major surfaces. Such a stack may further comprise a first high index of refraction conductive outer layer 82 with a first major surface that is disposed on, and in direct contact with, first major surface 52 of substrate 50 and that thus provides first major surface 62 of transparent conductive layer 60, and a second major surface that is disposed on, and in direct contact with, the first major surface of the core layer of the multilayer stack. Such a stack may further comprise a second high index of refraction conductive outer layer 86 with a first major surface that is disposed on, and in direct contact with, the second major surface of the core layer, and with a second major surface that provides second major surface 64 of transparent conductive layer 60.

The terms high and low index of refraction (RI) are defined relative to each other, and mean that high and low index of refraction materials differ from each other in index of refraction (specifically, the “real” part thereof) by at least 0.5 (when measured at a wavelength of approximately 630 nm). In further embodiments, the refractive index of the high and low RI materials may differ by at least about 0.8, or 1.0, again when measured at approximately 630 nm. By way of specific examples, metals such as silver and gold may comprise an RI in the range of e.g. 0.1 to 0.2 while metal oxides such as e.g. aluminum-doped zinc oxide, indium zinc oxide, and indium tin oxide may comprise an RI in the range of e.g. 1.8-2.1.

In some embodiments, low index of refraction core layer 84 may be comprised of metal. In specific embodiments, it may be comprised of gold, silver, (e.g. silver nanowires), and the like. It will of course be appreciated that such a metal layer should be conveniently provided in sufficiently low thickness as to preserve the desired optical clarity and to minimize reflectance, discoloration, and so on. In various embodiments, core layer 84 may be at most about 30, 20, 15, or 10 nm in thickness. In further embodiments, core layer 84 may be at least about 1, 2, or 4 nm in thickness.

In some embodiments, high index of refraction outer layers 82 and 86 may be comprised of a metal oxide (noting that the two outer layers do not necessarily have to be comprised of the same material). Such a metal oxide may be chosen from e.g. indium zinc oxide (IZO), aluminum-doped zinc oxide (AZO), indium tin oxide (ITO), and the like. Due to the properties of such materials, at least one of outer layers 82 and 86 may be able to be provided as somewhat thicker layers than core layer 84. In various embodiments, outer layers 82 and/or 86 may be at least about 2, 4, 8, 10, 20, 30, or 40 nm in thickness. In further embodiments, outer layers 82 and/or 86 may be at most about 100, 80, 60, 50, or 40 nm in thickness. In some embodiments, the thickness of first high index of refraction conductive outer layer 82 and the thickness of second high index of refraction conductive outer layer 86 may be within about 20%, 10%, or 5% of each other. However, in other embodiments the thickness of one such high index of refraction conductive outer layer may differ from that of the other high index of refraction outer layer by at least about 20%, 40%, 80%, 120%, or 200%. In such embodiments, either the first or the second high index of refraction conductive outer layer may be the thicker of the two. In particular embodiments, the thickness of first high index of refraction conductive outer layer 82 (that is located between low index of refraction conductive core layer 84 and substrate 50) may be significantly less than the thickness of second high index of refraction conductive outer layer 86. In such embodiments, the thickness of layer 82 may range from about 2, 3, or 4 nm to about 12, 10 or 8 nm, in combination with a layer 86 with a thickness that may range from about 15, 20 or 25 nm to about 60, 50 or 40 nm.

It will be appreciated that a multilayer stack of this general type (e.g., with a highly conductive metal core layer sandwiched between two metal oxide layers) may exhibit an advantageously low sheet resistance, while at the same time exhibiting advantageously high optical transmission. Regardless of the particular composition, the thicknesses of the layers of such a stack may be conveniently chosen so that the stack forms or approximates a quarter-wave stack so as to minimize internal interfacial reflection at the wavelengths of interest.

In some embodiments, transparent conductive layer 60 (e.g., a transparent conductive multilayer stack) does not comprise, and is not in contact with, any layer of organic polymeric material that is not transparent organic polymeric flexible substrate 50 or an optically clear adhesive (as described later herein, and that may be applied to major surface 64 of transparent conductive layer 60 to facilitate the attaching of assembly 40 to e.g. a touch screen module). Thus in such embodiments, the presence of any organic polymeric layer (whether characterized e.g. as a barrier layer, a dielectric layer, an insulating layer, a protecting layer, and so on), e.g. between any layers of a multilayer conductive stack, is prohibited. In further embodiments, such a transparent conductive multilayer stack does not include any layers (whether of metal, metal oxide, organic polymer, and so on) besides the core layer and the first and second outer layers (whether such additional layer is characterized as e.g. a seed layer, a nucleation layer, a barrier layer, a protective layer, a dielectric layer, and so on).

Transparent conductive layer 60 may be disposed directly on first major surface 52 of substrate 50 by any suitable means, e.g. physical vapor deposition, chemical vapor deposition, coating, printing (e.g., of conductive ink), and so on (noting that there may not always be bright-line differences between deposition methods such as e.g. coating and printing). If transparent conductive layer 60 is a multilayer stack, the individual layers thereof may be deposited (e.g., sequentially) by any of these methods, alone or in combination. In various embodiments, any or all of the various conductive layers of such a conductive multilayer stack may be continuous or discontinuous.

Antireflective layer 70 can be comprised of any suitable transparent material that exhibits appropriate antireflective properties, provided in any manner. In some embodiments, antireflective layer 70 may take the form of a multilayer optical quarter-wave stack (in which the individual (sub)layers of layer 70 provide destructive interference of light waves reflected from interfaces therebetween at the wavelengths of interest). However (particularly if assembly 40 is to be positioned in front of an optical display so that light emitted from the display must pass through assembly 40), it may be advantageous that layer 70 be a type of antireflective layer that minimizes reflection from an external surface thereof rather than a type that relies on destructive interference of light reflected from an external surface thereof with other light that is reflected from internal interfaces of a multilayer antireflective structure. Such a mode of operation may maximize the amount of light that is transmitted through assembly 40, rather than merely minimizing the amount of light that is reflected therefrom. Such an arrangement may be profitably used e.g. when antireflective layer 70 comprises an air interface at which incoming light that is emitted from an optical display impinges on the outer surface (e.g., surface 74) of layer 70.

Such a mode of antireflection may be provided by e.g. any layer that comprises features on a light-facing outer (e.g., air-gap-facing) surface thereof (e.g. major surface 74), which features are in the range of the wavelength of visible light of interest. In other words, such features may be nanosized so as to minimize the effects of a refractive index mismatch between the air of an air gap, and the material of which layer 70 is made.

Thus in some embodiments, major surface 74 of antireflective layer 70 comprises a nanostructured layer, by which is meant that major surface 74 exhibits a multiplicity of features that each exhibit a characteristic length, in at least two of the three possible dimensions (in/out of the major plane of the layer, and in each direction along the plane of the film), in the range of from about 800 nm to about 10 nm. Such nanofeatures may be provided in a regular or repeating pattern, or in a random or irregular pattern. The individual nanofeatures of such a nanostructured may take any suitable form (e.g., nanopillars, moth-eye structures, and so on); the individual nanofeatures may be alike in size and/or shape, or may vary greatly from nanofeature to nanofeature. A nanofeature, in this context, can be anything that represents a departure or deviation from a flat planar surface. Nanofeatures can include those that protrude (nodules, posts, lumps, ridges, for example), or those which are recessed (holes, pits, fissures, crevices, for example). The microstructured surface may also possess a combination of protruding and recessed features (for example, protruding and recessed pyramids).

Such a nanostructured surface may be obtained in any suitable manner and may have any structure and composition that can provide the desired antireflective properties. In some embodiments, such a nanostructured surface comprise a polymeric matrix with submicrometer particles dispersed therein, e.g. at least in a region at or near to one major surface of the polymeric matrix. Such a nanostructured surface may be conveniently obtained e.g. by providing a curable resin comprising submicrometer particles dispersed therein and curing a layer of the resin in the presence of an inhibitor gas that inhibits curing of the resin at an outer surface region of the layer, yielding a surface comprising at least partially protruding submicrometer particles. The surface region can then be subsequently cured thus providing a product with a nanostructured surface. Further details of such processes and the resulting nanostructured surfaces are described in detail in US Provisional Patent Application 61/593,666, entitled Nanostructured Materials and Methods of Making the Same, filed 1 Feb. 2012; and, in PCT Patent Application Publication WO 2013/116103 which claimed priority thereto. Both of these documents are incorporated by reference in their entirety herein for this purpose.

In some other embodiments, such a nanostructured surface may be conveniently obtained e.g. by providing a matrix comprising a nanodispersed phase (provided by e.g. silica nanoparticles) and etching the matrix using e.g. plasma treatment. Further details of such processes and the resulting nanostructured surfaces are described in detail in U.S. Patent Application Publication 2011/0281068, which is incorporated by reference in its entirety herein for this purpose.

However provided, in various embodiments antireflective layer 70 (as provided on a major surface of a substrate) may exhibit a reflectivity that is less than about 3.5, 3.0, 2.5, or 2.0, e.g. when visible light at a wavelength of about 630 nm is impinged in a direction aligned with the shortest dimension of layer 70 and of the substrate). In various embodiments, the optical transmittance of transparent multilayer assembly 40 may be at least about 86, 88, 89, 90, or 91%. In further embodiments, the optical transmittance of assembly 40 may be at most about 94%. In various embodiments, the sheet resistivity of transparent conductive layer 60 of assembly 40 may be less than about 100, 80, 60, 50, 40, 30, or 20 Ohm/sq. In further embodiments, the sheet resistivity of layer 60 may be at least about 5 Ohm/sq. In particular embodiments, the optical transmittance of transparent multilayer assembly 40 is greater than 88% and the sheet resistivity of transparent conductive layer 60 is lower than 40 Ohm/sq. In other particular embodiments, the optical transmittance of transparent multilayer assembly 40 is greater than 90% and the resistivity of the transparent conductive layer is in the range of from 40 or 50 to about 500 Ohm/sq (noting that in order to provide very high transparency it may be possible to accept lower conductivity). In various embodiments, assembly 40 (when viewed along its shortest dimension) may exhibit “a*” and “b*” values (when measured on a CIE L*a*b* scale) with an absolute value of less than about 4, 3, 2, or 1.0. In various embodiments, assembly 40 exhibits a haze (when viewed along its shortest dimension) of less than about 10%, 5%, or 2%.

In some embodiments, transparent multilayer assembly 40 consists essentially of transparent organic polymeric flexible substrate 50, transparent conductive layer 60, and antireflective layer 70 on the opposite side of substrate 50 from conductive layer 60. In such embodiments, assembly 40 may not comprise any layer of organic polymeric material other than transparent organic polymeric flexible substrate 50 (noting however that in certain embodiments substrate 50 might itself be a multilayer substrate and also noting that in some embodiments conductive layer 60 may be in contact with an optically clear adhesive layer that is used to bond assembly 40 to e.g. a touch screen module). In such embodiments, assembly 40 likewise may not comprise any additional layer of inorganic material (e.g., metal or metal oxide) beyond such layers or sublayers as may be present in conductive layer 60. It is noted that this condition does not preclude the presence of some inorganic material (e.g., silica nanoparticles) in certain types of antireflective layers 70.

In some embodiments, transparent multilayer assembly 40 may be combined with an optically clear adhesive (OCA) 94 to form a multilayer electromagnetic interference (EMI) shielding assembly 10 as shown in exemplary manner in FIG. 3. (The term EMI shielding assembly is used for convenience, noting that the presence of an adhesive is not necessary for assembly 40 to be able to provide EMI shielding.) Optically clear adhesive 94 may comprise a first major surface that in some embodiments is disposed on, and is in direct contact with, the second major surface 64 of transparent conductive layer 60 to form EMI shielding assembly 10.

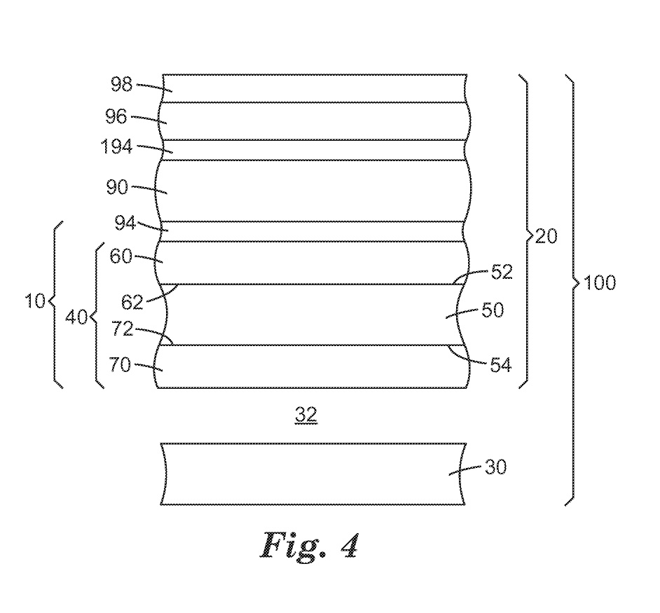

Optically clear adhesive 94 may be any suitable adhesive that is sufficiently optically clear (meaning that the adhesive has an optical transmission value of at least 85% when measured at a thickness of about 50 microns) and that can satisfactorily bond assembly 40 to e.g. a touch screen module as described below. In various embodiments optically clear adhesive 94 may exhibit an optical transmission of at least about 90%, and/or a haze value of less about 10%, 5%, or 2%. In some embodiments, optically clear adhesive 94 may take the form of a pressure-sensitive adhesive that needs no further processing, activation, curing or the like, to perform its bonding function. In other embodiments, optically clear adhesive may take the form of a liquid resin or of a semi-liquid pressure sensitive adhesive that is activated (e.g., cured, such as by heat exposure or the like) to achieve its final bonding properties. In many embodiments, optically clear adhesive 94 may be non-conductive, although in some embodiments it might be conductive as described e.g. in PCT Patent Application Publication WO 2013/025330. Suitable materials for use in an optically clear adhesive may include, for example, those based on natural rubbers, synthetic rubbers, styrene block copolymers, (meth)acrylic block copolymers, polyvinyl ethers, polyolefins, and poly(meth)acrylates. The terms (meth)acrylate and (meth)acrylic include both acrylates and methacrylates, which may be particularly suitable. Materials that may be suitable for use in an optically clear adhesive are described in further detail e.g. in PCT Patent Application Publication WO 2013/025330, which is incorporated by reference herein in its entirety for this purpose. A release liner can be provided on the major surface of the optically clear adhesive that is opposite assembly 40, so that EMI shielding assembly 10 can be supplied (e.g., whether in sheet form or as a roll good) to a producer of e.g. touch screens and/or touch screen displays. Any suitable release liner may be used as desired. In some embodiments, EMI shielding assembly 10 as described above may be combined with a touch-sensing unit 90 to form a touch screen module 20 (specifically, an EMI-shielded touch screen module) as shown in FIG. 4. In many embodiments, touch-sensing unit 90 may be a capacitive sensing unit, e.g. a projected-capacitance (“pro-cap”) sensing unit. The combining of assembly 10 with a touch-sensing unit 90 may be achieved by bonding the second major surface of optically clear adhesive 94 to a first major surface of touch-sensing unit 90. In some embodiments, touch-sensing unit 90 may optionally comprise additional layers and/or components beyond e.g. the various layers of a particular sensing apparatus. For example, in the exemplary illustration of FIG. 4, a so-called cover glass or cover lens 96 (which may be made of e.g. glass, polyester, polycarbonate, poly (methyl methacrylate), or the like) is bonded (by way of a secondary optically clear adhesive 194) to touch-sensing unit 90. Furthermore, as shown in FIG. 4 an additional optional protective layer 98, which might e.g. impart abrasion resistance to the outermost surface of unit 90 that will be touched in use, can be provided.

It will be appreciated that touch-sensing unit 90 may or may not already have e.g. a cover glass attached thereto at the time at which EMI shielding assembly 10 is attached to unit 90. It will further be appreciated that in some embodiments one or more layers or components of touch-sensing unit 90 may be combined with, replaced by, etc., a cover glass or a component thereof. By way of specific example, a conductive layer of a pro-cap touch-sensing unit may be deposited onto a (rear-facing) major surface of such a cover glass, thus potentially allowing a glass layer to be omitted from touch-sensing unit 90. The ordinary artisan will appreciate that there are countless variations and arrangements of such touch-sensing units, cover glasses, and so on. These variations notwithstanding, EMI shielding assembly 10 may be advantageously used with any such touch-sensing unit 90 (i.e., positioned between unit 90 and an optical display).

As also shown in FIG. 4, in some embodiments, EMI shielded touch screen module 20 may be combined with an optical display 30 to form a touch screen display 100. (Optical display 30 may operate by any suitable mechanism, e.g. liquid-crystal (LCD), OLED, and so on.) As mentioned, the presence of EMI-shielding assembly 10 can minimize any interference of optical display 30, with touch-sensing unit 90. This combining may be achieved by positioning optical display 30 adjacent second major surface 74 of antireflective layer 70 of transparent multilayer assembly 10 with an air gap 32 between a first major surface of the optical display and second major surface 74 of the antireflective layer, as shown in exemplary manner in FIG. 4. In various embodiments, air gap 32 may be at least about 0.1, 0.2, or 0.4 mm in average dimension; in further embodiments, air gap 32 may be at most about 2, 1, or 0.6 mm in average dimension. FIG. 4 of course shows only a representative portion of touch screen display 100; it will be appreciated that at various locations of the display (e.g., along the perimeter thereof), various connectors, gaskets, and so on may be used, so that that the illustrated air gap may only be present over the actual viewing area of the display. In some embodiments, e.g. in the case of large touch screen displays, one or more spacing elements may be provided somewhere over the area occupied by the air gap and/or around the perimeter of the touch screen display, in order to provide enhanced support. Such a spacing element might be e.g. any suitably electrically insulative element, e.g. a foam tape or the like.

Based on the disclosures herein it will be appreciated that the presence of antireflective layer 70 facing the optical display 30, as achieved by providing antireflective layer 70 on the opposite side of substrate 50 from conductive layer 60, can provide that light emitted from optical display 30 is transmitted through assembly 10, and indeed through the entirety of touch screen module 20, with high fidelity.

### LIST OF EXEMPLARY EMBODIMENTS

Embodiment 1 is a transparent multilayer assembly, comprising: a transparent organic polymeric flexible substrate having first and second, opposed major surfaces; a transparent conductive layer having first and second, opposed major surfaces with the first major surface of the transparent conductive layer being disposed on, and in direct contact with, the first major surface of the substrate, and, an antireflective layer having first and second, opposed major surfaces with the first major surface of the antireflective layer being disposed on, and in direct contact with, the second major surface of the transparent organic polymeric flexible substrate.

Embodiment 2 is the transparent multilayer assembly of embodiment 1 wherein the transparent conductive layer is a transparent conductive multilayer stack comprising: a conductive, low index of refraction core layer with first and second opposed major surfaces; a first conductive high index of refraction outer layer with a first major surface that is disposed on, and in direct contact with, the first major surface of the substrate and that provides the first major surface of the transparent conductive layer, and with a second major surface that is disposed on, and in direct contact with, the first major surface of the core layer of the multilayer stack; and, a second high index of refraction outer layer with a first major surface that is disposed on, and in direct contact with, the second major surface of the core layer and with a second major surface that provides the second major surface of the transparent conductive layer.

Embodiment 3 is the transparent multilayer assembly of embodiment 2 wherein the first and second outer layers of the transparent conductive multilayer stack are each chosen from the group consisting of indium zinc oxide, aluminum zinc oxide, and mixtures and blends thereof. Embodiment 4 is the transparent multilayer assembly of any of embodiments 2-3 wherein the conductive, low index of refraction core layer is a metal layer. Embodiment 5 is the transparent multilayer assembly of any of embodiments 2-4 wherein the transparent conductive multilayer stack does not comprise, and is not in contact with, any layer of organic polymeric material that is not the transparent organic polymeric flexible substrate or an optically clear adhesive. Embodiment 6 is the transparent multilayer assembly of any of embodiments 2-5 wherein the transparent conductive multilayer stack does not include any other layers besides the core layer and the first and second outer layers. Embodiment 7 is the transparent multilayer assembly of any of embodiments 2-6 wherein the transparent conductive layer comprises a conductive material chosen from the group consisting of silver nanowires, graphene, carbon nanotubes, and wire mesh.

Embodiment 8 is the transparent multilayer assembly of any of embodiments 1-7 wherein the transparent organic polymeric flexible substrate consists of a single organic polymeric film of uniform composition throughout the thickness of the film. Embodiment 9 is the transparent multilayer assembly of any of embodiments 1-7 wherein the transparent organic polymeric flexible substrate comprises an organic polymeric film with at least one layer of organic polymeric material provided on a major surface thereof by vapor deposition, so that a major surface of the vapor-deposited layer of organic polymeric material provides a major surface of the transparent organic polymeric flexible substrate.

Embodiment 10 is the transparent multilayer assembly of any of embodiments 1-9 wherein the antireflective layer is a multilayer optical quarter-wave stack. Embodiment 11 is the transparent multilayer assembly of any of embodiments 1-9 wherein the second major surface of the antireflective layer is a nanostructured surface. Embodiment 12 is the transparent multilayer assembly of any of embodiments 1-11 wherein the optical transmittance of the transparent multilayer assembly is greater than 88% and the sheet resistivity of the transparent conductive layer is lower than 40 Ohm/sq. Embodiment 13 is the transparent multilayer assembly of any of embodiments 1-11 wherein the optical transmittance of the transparent multilayer assembly is greater than 90% and the resistivity of the transparent conductive layer is between about 50 and about 500 Ohm/sq. Embodiment 14 is the transparent multilayer assembly of any of embodiments 1-13 wherein the assembly consists essentially of the transparent organic polymeric flexible substrate, the transparent conductive layer, and the antireflective layer, and wherein the assembly does not comprise any layer of organic polymeric material other than the transparent organic polymeric flexible substrate.

Embodiment 15 is a multilayer electromagnetic interference shielding assembly comprising the transparent multilayer assembly of any of embodiments 1-14 in combination with an optically clear adhesive with a first major surface that is disposed on, and in direct contact with, the second major surface of the transparent conductive layer. Embodiment 16 is the touch screen module comprising the multilayer electromagnetic shielding assembly of embodiment 15 wherein a second major surface of the optically clear adhesive is disposed on, and in direct contact with, a first major surface of a touch-sensing unit. Embodiment 17 is the touch screen display comprising the touch screen module of embodiment 16 in combination with an optical display that is positioned adjacent the second major surface of the antireflective layer of the transparent multilayer assembly of the touch screen module with an air gap between a first major surface of the optical display and the second major surface of the antireflective layer.

### EXAMPLES

### Experimental Methods

Measurement of total optical transmission (sometimes referred to as optical transmittance), and reflectance, over e.g. the range of 250-800 nm, and the measurement of color properties, can be performed by the use of a spectrophotometer of the general type available from e.g. Perkin-Elmer under the trade designation Lambda 950, along with an integrating sphere. Optical transmittance can be reported e.g. as total luminous transmittance, reported in percent. Reflectance can be reported in percent. Color properties can be reported e.g. as L*, a*, and b* values on a CIE scale.

Measurement of haze can be performed by the use of a haze meter of the general type available from BYK Gardner under the trade designation “BYK HAZEGARD PLUS” from BYK Gardiner, with results reported in percent.

Measurement of electrical sheet resistance can be performed with by way of four-terminal testing (also referred to as four point probe testing), with results reported in Ohm/sq.

Measurement of EMI shielding efficiency can be performed using a network analyzer of the general type available from Agilent under the trade designation E5701C), with the sample being placed between a source and receiver, and with a scan range of 30 MHz-1.5 GHz. Results can be reported in decibels (dB) of attenuation.

### Representative Example

An optical grade polyester film substrate of approximately 75 μm thickness was obtained of the general type available from Mitsubishi under trade designation 4507. A nanostructured antireflective layer was formed on one major surface of the polyester film, in general accordance with the procedures outlined in the Examples of PCT Patent Application Publication WO 2013/116103. In further detail, surface-modified silica nanoparticles (of average size in the range of approximately 100 nm) were prepared in general accordance with Preparatory Example 8 of the '6103 publication. The nanoparticles were then mixed with a prepolymer resin and coated onto the film substrate and cured in the presence of oxygen in general accordance with the procedures of Example 11 of the '6103 publication. A transparent conductive multilayer stack was then formed on the other major surface of the polyester film. Formation (deposition/processing) of the antireflective layer was performed by roll-to-roll processing with the polyester film in the form of a continuous roll; sheet samples of the AR-coated film were then cut from the film and the various conductive layers were deposited in batch mode by sputter coating as described below.

The transparent conductive multilayer stack comprised a three-layer IZO/Ag/IZO sandwich. A first IZO outer layer was sputter coated directly onto the surface of the polyester film (opposite the surface bearing the AR coating) and had an estimated thickness in the range of approximately 6-7 nm. The Ag core layer was then sputter coated to an estimated thickness in the range of approximately 6-7 nm, after which the second outer layer of IZO was sputter coated atop the Ag core layer to an estimated thickness in the range of approximately 30-35 nm to provide the three layer stack. All three layers were believed to be continuous.

The resulting product was a transparent multilayer assembly of the general type depicted in FIG. 1 (specifically, with the conductive layer comprising a three-layer stack of the general type depicted in FIG. 2).

For typical samples of this construction, the optical transmittance (total luminous transmittance) of the polyester substrate (in the absence of any conductive layer or antireflective layer) was estimated to be in the range of approximately 90-91%. The optical transmittance of the polyester substrate with the three-layer conductive stack thereupon (in the absence of an antireflective layer) was in the range of approximately 85-86%. The optical transmittance of the polyester substrate with the antireflective layer thereupon (in the absence of any conductive layer) was in the range of approximately 93%. The optical transmittance of the polyester substrate with the three-layer conductive stack on one side thereof and the antireflective layer on the other side thereof (that is, of the entire transparent multilayer assembly), was in the range of approximately 90%.

For typical samples of this construction, the CIE L*, a*, and b* values (of the entire transparent multilayer assembly) were measured to be respectively in the range of approximately 95.2, -2.3, and 2.9. The sheet resistance of the three-layer conductive stack was measured to be in the range of approximately 13-15 Ohm/sq. The EMI shielding efficiency was measured to be in the range of approximately 20 dB of attenuation.

The foregoing Examples have been provided for clarity of understanding only, and no unnecessary limitations are to be understood therefrom. The tests and test results described in the Examples are intended to be illustrative rather than predictive, and variations in the testing procedure can be expected to yield different results. All quantitative values in the Examples are understood to be approximate in view of the commonly known tolerances involved in the procedures used.

It will be apparent to those skilled in the art that the specific exemplary elements, structures, features, details, configurations, etc., that are disclosed herein can be modified and/or combined in numerous embodiments. (In particular, any of the elements that are positively recited in this specification as alternatives, may be explicitly included in the claims or excluded from the claims, in any combination as desired.) All such variations and combinations are contemplated by the inventor as being within the bounds of the conceived invention not merely those representative designs that were chosen to serve as exemplary illustrations. Thus, the scope of the present invention should not be limited to the specific illustrative structures described herein, but rather extends at least to the structures described by the language of the claims, and the equivalents of those structures. To the extent that there is a conflict or discrepancy between this specification as written and the disclosure in any document incorporated by reference herein, this specification as written will control.

What is claimed is:

1. A transparent multilayer assembly, comprising:
a transparent organic polymeric flexible substrate having first and second, opposed major surfaces;
a transparent conductive layer having first and second, opposed major surfaces with the first major surface of the transparent conductive layer being disposed on, and in direct contact with, the first major surface of the substrate,
and,
an antireflective layer having first and second, opposed major surfaces with the first major surface of the antireflective layer being disposed on, and in direct contact with, the second major surface of the transparent organic polymeric flexible substrate.

2. The transparent multilayer assembly of claim 1 wherein the transparent conductive layer is a transparent conductive multilayer stack comprising:
a conductive, low index of refraction core layer with first and second opposed major surfaces;
a first conductive high index of refraction outer layer with a first major surface that is disposed on, and in direct contact with, the first major surface of the substrate and that provides the first major surface of the transparent conductive layer, and with a second major surface that is disposed on, and in direct contact with, the first major surface of the core layer of the multilayer stack; and,
a second high index of refraction outer layer with a first major surface that is disposed on, and in direct contact with, the second major surface of the core layer and with a second major surface that provides the second major surface of the transparent conductive layer.

3. The transparent multilayer assembly of claim 2 wherein the first and second outer layers of the transparent conductive multilayer stack are each chosen from the group consisting of indium zinc oxide, aluminum zinc oxide, and mixtures and blends thereof.

4. The transparent multilayer assembly of claim 2 wherein the conductive, low index of refraction core layer is a metal layer.

5. The transparent multilayer assembly of claim 2 wherein the transparent conductive multilayer stack does not comprise, and is not in contact with, any layer of organic polymeric material that is not the transparent organic polymeric flexible substrate or an optically clear adhesive.

6. The transparent multilayer assembly of claim 2 wherein the transparent conductive multilayer stack does not include any other layers besides the core layer and the first and second outer layers.

7. The transparent multilayer assembly of claim 2 wherein the transparent conductive layer comprises a conductive material chosen from the group consisting of silver nanowires, graphene, carbon nanotubes, and wire mesh.

8. The transparent multilayer assembly of claim 1 wherein the transparent organic polymeric flexible substrate consists of a single organic polymeric film of uniform composition throughout the thickness of the film.

9. The transparent multilayer assembly of claim 1 wherein the transparent organic polymeric flexible substrate comprises an organic polymeric film with at least one layer of organic polymeric material provided on a major surface thereof by vapor deposition, so that a major surface of the vapor-deposited layer of organic polymeric material provides a major surface of the transparent organic polymeric flexible substrate.

10. The transparent multilayer assembly of claim 1 wherein the antireflective layer is a multilayer optical quarter-wave stack.

11. The transparent multilayer assembly of claim 1 wherein the second major surface of the antireflective layer is a nanostructured surface.

12. The transparent multilayer assembly of claim 1 wherein the optical transmittance of the transparent multilayer assembly is greater than 88% and the sheet resistivity of the transparent conductive layer is lower than 40 Ohm/sq.

13. The transparent multilayer assembly of claim 1 wherein the optical transmittance of the transparent multilayer assembly is greater than 90% and the resistivity of the transparent conductive layer is between about 50 and about 500 Ohm/sq.

14. The transparent multilayer assembly of claim 1 wherein the assembly consists essentially of the transparent organic polymeric flexible substrate, the transparent conductive layer, and the antireflective layer, and wherein the assembly does not comprise any layer of organic polymeric material other than the transparent organic polymeric flexible substrate.

15. A multilayer electromagnetic interference shielding assembly comprising the transparent multilayer assembly of claim 1 in combination with an optically clear adhesive with a first major surface that is disposed on, and in direct contact with, the second major surface of the transparent conductive layer.

16. A touch screen module comprising the multilayer electromagnetic shielding assembly of claim 15 wherein a second major surface of the optically clear adhesive is disposed on, and in direct contact with, a first major surface of a touch-sensing unit.

17. A touch screen display comprising the touch screen module of claim 16 in combination with an optical display that is positioned adjacent the second major surface of the antireflective layer of the transparent multilayer assembly of the touch screen module with an air gap between a first major surface of the optical display and the second major surface of the antireflective layer.
